(19) United States
(12) Patent Application Publication
(10) Pub. No.: US 2013/0015323 A1
(43) Pub. Date: Jan. 17, 2013

(54) IMAGE SENSOR WITH A CHARGE-BASED READOUT CIRCUIT

(71) Applicants: Mark T. SAYUK, Reading, MA (US); Steven J. DECKER, Sandown, NH (US)

(72) Inventors: Mark T. SAYUK, Reading, MA (US); Steven J. DECKER, Sandown, NH (US)

(73) Assignee: ANALOG DEVICES, INC., Norwood, MA (US)

(21) Appl. No.: 13/517,524

(22) Filed: Jun. 13, 2012

Related U.S. Application Data
(60) Provisional application No. 61/507,980, filed on Jul. 14, 2011.

(51) Int. Cl. H01L 27/148

(52) U.S. Cl. 250/208.1

(57) ABSTRACT

Embodiments of the present invention employ a charged-based readout circuit in an image sensing system that includes a column readout circuit which may perform sampling on signals received from a pixel array and transfer a corresponding correlated double sample (CDS) signal, a differential channel readout circuit that may receive the corresponding CDS signal and amplify the signal using an output amplifier, and an output buffer which may receive the amplified CDS signal and output a corresponding signal out of the system. The output amplifier may be composed of two output amplifier paths so that ping-ponging is possible.

### BACKGROUND

The present invention relates to image sensing technology that utilizes a charge-based readout circuit performing correlated double sampling. Additionally, the invention may employ a ping-pong technique to enhance the overall performance of an image sensor.

Complementary metal-oxide-semiconductor (CMOS) image sensors, which are a type of active-pixel sensor (APS), typically are used in digital cameras to convert optical signals received by a pixel array to electronic signals. CMOS image sensors contain a plurality of sensor elements (or pixel circuits) which form a pixel array of columns and rows (say, N columns and M rows). When an image is detected by the pixel array, pixel circuits in the pixel array generate an electric signal corresponding to image information at each pixel location. Each pixel circuit contains a photosensitive component, such as a photodiode, which converts light signals into electric signals, and an amplifier, which amplifies the electric signals generated by the photosensitive component. The electric signals then are converted into the digital domain using analog-to-digital converters (ADCs) for signal processing purposes.

Many commercially available CMOS sensors employ a technique called column-parallel analog-to-digital conversion. This technique provides a single ADC for each column of a pixel array, digitizes pixel data from the array at the columns, and transfers that information off the sensor in the digital domain. There are two fundamental problems with this technique. First, increasing the number of ADCs on a chip increases power consumption and therefore raises the temperature of the sensor. This increase in temperature is disadvantageous because temperature is directly related to noise power. Second, mismatches in both offsets and gain errors of multiple ADCs may contribute to fixed-pattern noise in a sensor and can appear as image artifacts when the image data is displayed.

Thus, the inventor perceives a need in the art for a readout system in an image sensor that is low power and accurate.

### BRIEF DESCRIPTION OF THE DRAWINGS

FIG. 1 is a block diagram of an image sensing system that includes a pixel array and a readout system according to an embodiment of the present invention.

FIG. 2 illustrates an exemplary circuit configuration of a readout system according to an embodiment of the present invention.

FIG. 3 illustrates an exemplary circuit configuration of a readout system according to another embodiment of the present invention.

FIG. 4 is a timing diagram that illustrates the timing of the ping-pong operation according to the embodiment of the present invention described with reference to FIG. 3.

### DETAILED DESCRIPTION

Embodiments of the present invention may provide a charged-based readout system for an image sensor that includes a plurality of column readout circuits and a differential channel readout circuit selectively connected to the column readout circuits. A column readout circuit may perform sampling on signals received from a pixel array and may transfer a corresponding correlated double sample (CDS) signal to the differential channel readout circuit. The differential channel readout circuit may amplify CDS signals from the column readout circuits using an output amplifier system. The output amplifier system may be composed of two output amplifier paths so that ping-ponging is possible.

The readout system may operate in the charge domain, using an operational amplifier (op-amp) to force charge from a pair of input capacitors onto its feedback capacitors, where a voltage is developed. More precisely, the charge may be transferred from a pair of capacitors, allowing a correlated double sample operation by subtracting a sampled ‘reset’ charge from a sampled ‘signal’ charge (both of which are received from a pixel in a pixel array). The output of the amplifier, which is the voltage across the feedback capacitors, may then be buffered so this signal can be driven off chip.

Moreover, the circuit architecture permits one of the voltage supplies to the amplifier (e.g., VDD or ground) to be used as the amplifier input common-mode voltage. Use of an amplifier supply voltage as the input common-mode voltage allows high select switch conductance with low capacitance and, as a result, preserves high signal integrity. Accordingly, selection switches may be made smaller than for similar designs in which an input common-mode voltage were set at some other voltage, for example, ½ VDD.

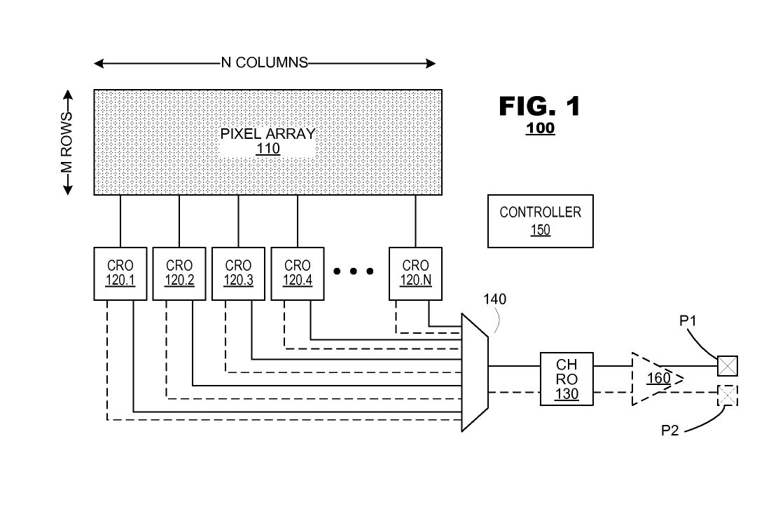

FIG. 1 is a simplified block diagram of an image sensor 100 according to an embodiment of the present invention. The image sensor 100 may include a pixel array 110 comprising a plurality of pixel circuits arranged into an array of N columns and M rows; a plurality of column readout circuits (CROs) 120.1-120.N, one provided for each columnar output of the pixel array 110; a differential channel readout circuit (CH RO) 130; routing fabric 140 (shown as differential multiplexer) connecting selected CROs 120.1-120.N to CH RO 130; and a controller 150 that manages operation of the image sensor 100. The components illustrated in FIG. 1 may be fabricated as a common integrated circuit.

During operation, the pixels are controlled to output reset (RST) values and signal (SIG) values to the CROs 120.1-120.N on a row-by-row basis. The RST values represent output signals generated by the pixels prior to exposure to incident light. Due to reset noise associated with resetting the pixel, the RST values from each pixel typically exhibit some variation from a nominal voltage. The SIG values represent output signals generated by the pixels after exposure to incident light. Because the incident light generally adds an additional signal value to an existing RST value, the same reset noise is typically present in both the RST and SIG values (i.e. they are correlated). Reset noise can therefore be removed by subtracting an RST sample from a SIG sample, also known as correlated double sampling.

The CROs 120.1-120.N may sample and store the RST and SIG signals from each pixel. Each CRO 120.1-120.N may be connected to the CH RO 130 by the router 140 in succession. When connected to the CH RO 130, each CRO 120.1-120.N may transfer a CDS signal to the CH RO 120 which may amplify the CDS signal and output it to the output pins P1, P2.

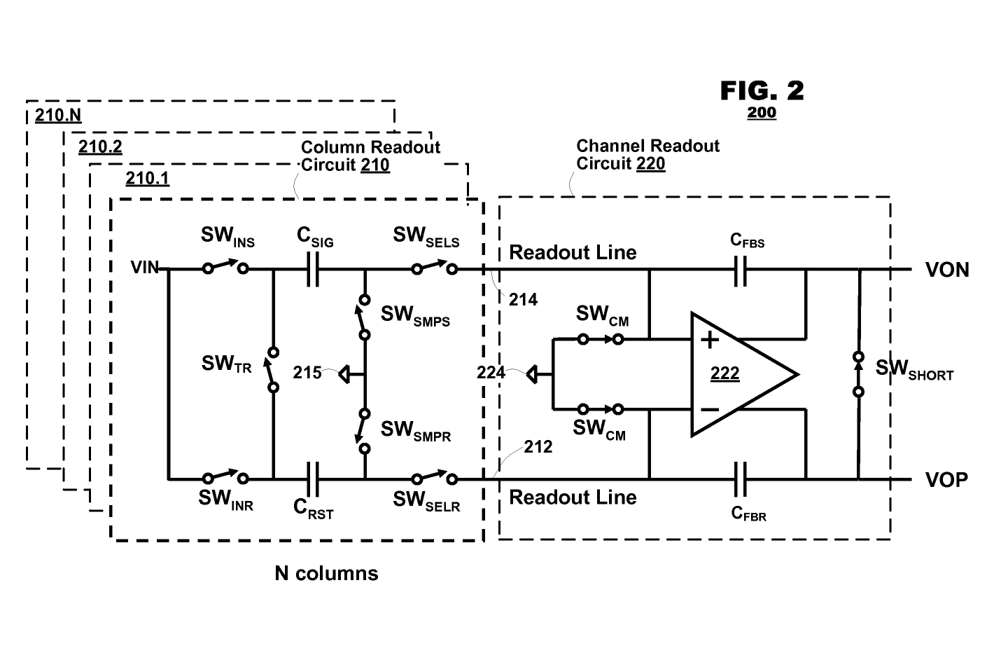

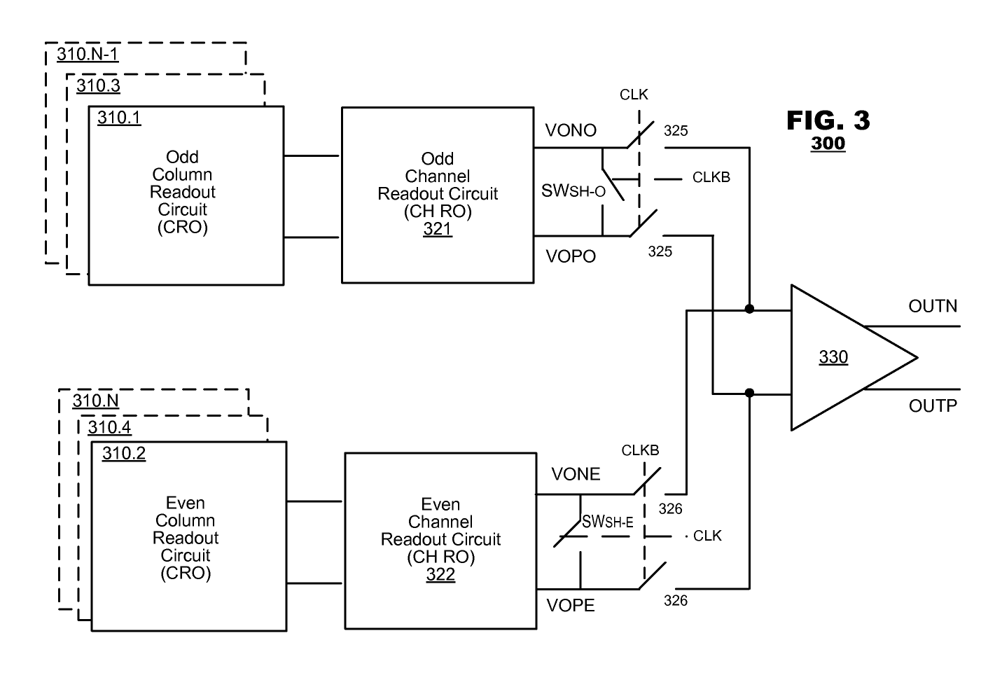

Controller 150 may be an on chip processor or state machine that controls operation of the pixel array, operation of switches in the CROs and CH ROs (described in FIGS. 2 and 3 below), and connection timing among the CROs 120.1-120.N and the CH RO 130. Such a machine may include, for example, any suitable processing platform, computing platform, computing device, processing device, computing system, processing system, computer, processor, or the like, and may be implemented using any suitable combination of hardware and/or software.

Optionally, an image sensor 100 may include multiple channels (not shown) each composed of its own CROs 120, multiplexer 140, CH RO 130, and output buffer 160. Color image sensors often utilize red, green, and blue pixels in a repeating pattern composed of 1 red pixel, 2 green pixels, and 1 blue pixel. In some systems, it may be desirable to read out the red and blue pixels on a first channel, and the green pixels on a second channel. In another system, it may be desirable to have 4 channels corresponding to 1 red, 1 blue, and 2 green. In yet other systems, it may be desirable to make the number of channels programmable via the routing fabric. Using multiple CH ROs 130 (not shown in FIG. 1) may increase the rate at which the image sensor may output image data from the integrated circuit at the cost of higher complexity, higher pin count, and additional offset sources, while channel programmability may increase noise.

FIG. 2 illustrates an exemplary circuit configuration of a readout system 200 according to an embodiment of the present invention. As discussed above, the readout system 200 may include several CROs 210.1-210.N and a differential CH RO 220. For simplicity, only the details of one CRO 210.1 and one CH RO 220 are illustrated in FIG. 2. The other CROs 210.2-210.N are substantially identical.

A CRO 210.1 may include an input terminal V_{IN}, a pair of sampling capacitors C_{SIG}, C_{RST}, input switches SW_{INS}, SW_{INR}, sampling switches SW_{SMPS}, SW_{SMPR}, a transfer switch SW_{TR} and select switches SW_{SELS}, SW_{SELR}. The input switches SW_{INS} and SW_{INR} may couple the input terminal V_{IN} selectively to first terminals of a respective sampling capacitor C_{SIG} or C_{RST}. Sampling switches SW_{SMPS}, SW_{SMPR} may couple second terminals of a respective sampling capacitor C_{SIG} or C_{RST} to a sampling voltage 215 (shown as ground, in the example of FIG. 2). The transfer switch SW_{TR} may short the first terminals of the sampling capacitors C_{SIG}, C_{RST} together. The output switches SW_{SELS}, SW_{SELR} may connect second terminals of a respective sampling capacitor C_{SIG} or C_{RST} to input terminals 214, 212 of the CH RO 220, labeled “readout lines.”

Operation of the CRO 210.1 may occur in several phases. In a first phase (or RST value sample phase), an RST value is output from a selected pixel in the pixel array to the CRO 210.1. During this time, a first input switch SW_{INR} and a first sampling switch SW_{SMPR} may be closed, causing a first sampling capacitor C_{RST} to capture a voltage representing the RST signal. At the conclusion of the first phase, the switches SW_{INR} and SW_{SMPR} may open, holding the captured voltage on sampling capacitor C_{RST}.

In a second phase (or SIG value sample phase), a SIG value is output from the selected pixel of the pixel array to the CRO 210.1. During this time, a second input switch SW_{INS} and a second sampling switch SW_{SMPS} may be closed, causing a second sampling capacitor C_{SIG} to capture a voltage representing the SIG signal. At the conclusion of the second phase, the switches SW_{INS} and SW_{SMPS} may open, holding the captured voltage on sampling capacitor C_{SIG}. At the conclusion of the second phase, the voltages on the first and second sampling capacitors C_{RST}, C_{SIG} may be held until the CRO 210.1 is connected to the CRO 220.

During a third phase (or transfer phase) of operation, the CRO 210.1 may be connected to the differential CH RO 220 by closing the select switches SW_{SELS}, SW_{SELR}. During the third phase, the transfer switch SW_{TR} also may be closed. Because SW_{TR} shorts the “sample” sides of C_{SIG} and C_{RST} together, closure of the transfer switch SW_{TR} allows the charge difference between the two sampling capacitors C_{SIG}, C_{RST} to be transferred to the CH RO 220. This charge difference represents a subtraction of the RST value from the SIG value (CDS signal).

During operation, the CROs 210.1-210.N may perform operations of the first and second phases in parallel with each other. That is, the CROs 210.1-210.N may capture RST and SIG values in common, parallel operations. The CROs 210.1-210.N each may perform their third phases in a staggered fashion because they share a common CH RO 220. Thus, the CH RO 220 may receive an output signal first from CRO 210.1 and may generate an output from it, then reset and receive an output signal from CRO 210.2. After the CH RO 220 receives output signals from all the CROs 210.1-210.N, the CROs 210.1-210.N may return to the first phase to receive RST and SIG values from selected pixels in another row of the pixel array.

FIG. 2 also illustrates components of the differential CH RO 220, which may include a differential op-amp 222, a pair of feedback capacitors C_{FBS} and C_{FBR} and control switches SW_{CM} and SW_{SHORT}. Inputs of the op-amp 222 may be coupled to outputs of the CROs 210.1-210.N, labeled as readout lines 212 and 214 respectively. A pair of feedback capacitors C_{FBS} and C_{FBR} may be connected one apiece between a respective input and a respective output of the op-amp 222. A pair of common-mode switches SW_{CM} may connect a respective one of the readout line 214 and readout line 212 to a common-mode voltage 224 that is one of the voltage supplies to the op-amp 222 (shown as ground, in the example of FIG. 2). A shorting switch SW_{SHORT} may couple the first and second outputs of op-amp 222 to each other.

The CH RO 220 also may operate in multiple phases of operation. During a reset phase, the CH RO 220 may be reset for a new iteration of operation. Specifically, the common-mode switches SW_{CM} and shorting switch SW_{SHORT} may be closed. Inputs of the op-amp 222 (readout lines 212 and 214) may be set to an identical voltage by the common-mode switches SW_{CM}. Similarly, output terminals of the op-amp 222 may be set to an identical voltage by the shorting switch SW_{SHORT}. Thus, voltages on the feedback capacitors C_{FBS} and C_{FBR} may be equalized.

In an amplification phase (which may coincide with the transfer phase of CRO 210.1), the switches SW_{CM} and SW_{SHORT} of the differential CH RO 220 may be opened. The differential CH RO 220 may receive the signal output from CRO 210.1. The feedback around op-amp 222 forces its inputs to be substantially identical, transferring the charge difference between C_{SIG} and C_{RST} to C_{FBS} and C_{FBR}, generating a differential voltage signal on output terminals VOP and VON.

Specifically, as described in the third phase (or transfer phase) of CRO 210.1, the charge difference between C_{SIG} and C_{RST} may be transferred to C_{FBS} and C_{FBR}. The negative feedback around differential op-amp 222 holds readout lines 212 and 214 at substantially identical voltages (0V differential). If the series combination of C_{SIG} and C_{RST} has 0V across it, there can be no net charge from the equation Q=CV, where Q is charge, C is capacitance, and V is voltage. Consequently, due to conservation of charge, the original charge is transferred to C_{FBS} and C_{FBR}. Because the charge is transferred from C_{SIG} and C_{RST} to C_{FBS} and C_{FBR}, the voltage across C_{SIG} and C_{RST} is amplified by a ratio of C_{SIG}/C_{FBS} or C_{RST}/C_{FBR} (assuming C_{SIG}=C_{RST} and C_{FBS}=C_{FBR}). This amplified signal is presented as a differential voltage signal at output terminals VOP and VON.

It is important to note that this simple CDS operation is a direct result of the differential charge transfer that takes place between CRO 210.1 and differential CH RO 220. Without the differential charge transfer, and accompanying differential architecture of the amplifier, this operation would be more complicated. Indeed, a common method of accomplishing this CDS is the use of individual column amplifiers which may lead to increased power consumption, required chip area, and fixed-pattern noise (FPN).

In the embodiment illustrated in FIG. 2, a single CH RO 220 may service all connected CROs 210.1-210.N of the image sensor. Thus, the CH RO 220 may cycle through N iterations of reset and transfer phases to output signals from N CROs on an image sensor. FIG. 1 illustrates routing fabric 140 between the CROs 120.1-120.N and the CH RO 130. In the embodiment illustrated in FIG. 2, the routing fabric is embodied as selection switches SW_{SELS} and SW_{SELR}. The selection switches SW_{SELS} and SW_{SELR} may be implemented with n-type metal-oxide-semiconductor field-effect transistors (NMOSFETs). When inputs of the op-amp 222 are set to a common-mode voltage 224 of 0V, it may cause the selection switches SW_{SELS} and SW_{SELR} to be maximally conductive. Thus, circuit designers can provide these switches with minimal sizing, which reduces parasitic capacitance on readout lines 212 and 214. Consequently, throughput may be increased and/or noise may be reduced in the system 200.

FIG. 3 illustrates an exemplary circuit configuration of a readout system 300 according to an embodiment of the present invention. The readout system 300 may be coupled to a pixel array containing a plurality of pixels arranged in a two-dimensional grid (e.g., N columns and M rows) (not shown in FIG. 3 but similar to the pixel array in FIG. 1), a plurality (N/2) of odd numbered column readout circuits (CROs) 310.1, 310.3 . . . , 310.N-1, a plurality (N/2) of even numbered column readout circuits (CROs) 310.2, 310.4 . . . , 310.N, an odd differential channel readout circuit (CH RO) 321, an even differential channel readout circuit (CH RO) 322, switches SW_{SH-O} and SW_{SH-E}, control switches 325 and 326, and common output buffer 330. Odd and even CROs 310.1-310.N may be connected to respective columns of a pixel array (as shown in FIG. 1). Switch SW_{SH-O} may connect outputs VONO and VOPO of odd CH RO 321 together. Switch SW_{SH-E} may connect outputs VONE and VOPE of even CH RO 322 together. Control switches 325 may connect odd CH RO 321 to common output buffer 330. Control switches 326 may connect even CH RO 322 to common output buffer 330.

Odd and even CROs 310.1-310.N may be substantially similar to the CRO 210.1 described above with respect to FIGS. 1 and 2. Specifically, each odd CRO 310.1-310.N-1 may operate in several phases including an RST value sample phase, a SIG value sample phase, and a transfer phase. However, each odd CRO 310.1-310.N-1 only samples RST and SIG values from a selected odd pixel in an odd column of the pixel array. Likewise, each even CRO 310.2-310.N may operate in several phases including an RST value sample phase, a SIG value sample phase, and a transfer phase. However, each even CRO 310.2-310.N only samples RST and SIG values from a selected even pixel in an even column of the pixel array.

Odd CH RO 321 and even CH RO 322 may be substantially similar to CH RO 220 described above with respect to FIGS. 1 and 2. Specifically, odd CH RO 321 may operate in multiple phases including a reset phase and an amplify phase. However, during the amplify phase, odd CH RO 321 amplifies a CDS signal from a selected one of the odd CROs 310.1-310.N-1. Likewise, even CH RO 322 may operate in multiple phases including a reset phase and an amplify phase. However, during the amplify phase, even CH RO 322 amplifies a CDS signal from a selected one of the even CROs 310.2-310.N.

Switches SW_{SH-O} and SW_{SH-E} may be similar to switch SW_{SHORT} described with respect to FIG. 2. During operation, switches SW_{SH-O} and SW_{SH-E} should be in opposite states (i.e., when SW_{SH-O} is closed, SW_{SH-E} is open, and vice versa).

Control switches 325 and 326 connect the respective CH ROs 321, 322 to common output buffer 330 based on control signals CLK and CLKB, respectively. Control signals CLK, CLKB may be controlled by an internal controller (not shown in FIG. 3 but similar to the controller shown in FIG. 1). Control switches 325 and 326 should also be in opposite states (i.e., when switches 325 are open, switches 326 are closed, and vice versa).

The common output buffer 330 may have inputs to receive output signals VONO, VOPO from the odd CH RO 321, and output signals VONE, VOPE from the even CH RO 322. Additionally, the common output buffer 330 may have differential outputs for outputting differential output signals OUTN and OUTP.

In the present embodiment, a respective one of the odd CROs 310.1-310.N-1 may be connected to odd CH RO 321, forming an “odd pixel signal chain.” Similarly, a respective one of the even CROs 310.2-310.N may be connected to even CH RO 322, forming an “even pixel signal chain.” Specifically, respective odd and even CROs 310.1-310.N may be connected to corresponding odd CH RO 321 and even CH RO 322 in a manner similar to how CRO 210.1 and CH RO 220 may be connected as described with reference to FIG. 2 (for example, they may be connected with switches similar to SW_{SELS} and SW_{SELR} in FIG. 2).

The general concept of operation of readout system 300 is as follows: while a respective “odd pixel signal chain” (formed by connecting a respective odd CRO 310.1-310.N-1 to odd CH RO 321) may be in one state (e.g., amplify), the “even pixel signal chain” (formed by connecting a respective even CRO 310.2-310.N to even CH RO 322) may be in another state (e.g., reset). Specifically, a controller (not shown in FIG. 3, but similar to controller 150 in FIG. 1) places the odd and even signal pixel chains in opposite states by controlling the switches in respective CROs and CH ROs (described in further detail below).

For example, while the sampled signals from one odd CRO (e.g., 310.1) are being amplified in the odd CH RO 321 during an amplify phase, switches 325 may be closed in response to a high control signal CLK and SW_{SH-O} may be opened. Amplified signals VONO and VOPO may be applied to inputs of common output buffer 330 and may be output as output signals OUTN and OUTP, which represent a selected odd pixel signal value after CDS has been performed for the respective odd pixel being read out.

In the above example, while the odd pixel signal chain is in the amplify phase, the even pixel signal chain may be in the reset phase. Specifically, in the reset phase, switches 326 may be open in response to a low control signal CLKB, and switch SW_{SH-E} may be closed to allow even CH RO 322 to reset as explained above with respect to FIG. 2. Opening switches 326 prevents the shorting switch SW_{SH-E} from interfering with the odd pixel signal being read out.

After the odd pixel signal chain completes the amplify phase and the even pixel signal chain completes the reset phase, the operations may switch, and the odd pixel signal chain may begin a reset phase, and the even pixel signal chain may begin an amplify phase. When the odd pixel signal chain is in a reset phase, switches 325 may be open in response to a low CLK signal and switch SW_{SH-O} may be closed. Opening switches 325 prevents the shorting switch SW_{SH-O} from interfering with the even pixel signal being read out.

When the even pixel signal chain is in an amplify phase, switches 326 may be closed in response to a high CLKB signal and SW_{SH-E} may be opened. Amplified signals VONE and VOPE may be output to common output buffer 330. Common output buffer 330 may then output differential signals OUTN and OUTP, which represent the CDS values for the respective even pixel being read out. The process may then switch back, and the respective operations may repeat for the next odd and even CROs. This process is known as “ping-ponging.”

In the embodiment illustrated in FIG. 3, a single odd CH RO 321 may service all connected odd CROs 310.1-310.N-1. Similarly, a single even CH RO 322 may service all connected even CROs 310.2-310.N. Thus, odd and even CH ROs 321 and 322 may each cycle through N/2 iterations of reset and transfer phases to output signals from N CROs of an image sensor.

Advantages of the ping-ponging process described above in readout system 300 include reducing noise and providing a better power/speed trade-off. The configuration cuts the number of select switches for any one amplifier in half, thus reducing the parasitic capacitance on the amplifiers' summing nodes which may reduce noise. In addition, the use of two amplifiers means each can run at half the speed, allowing for a better power/speed trade-off than is possible with one amplifier.

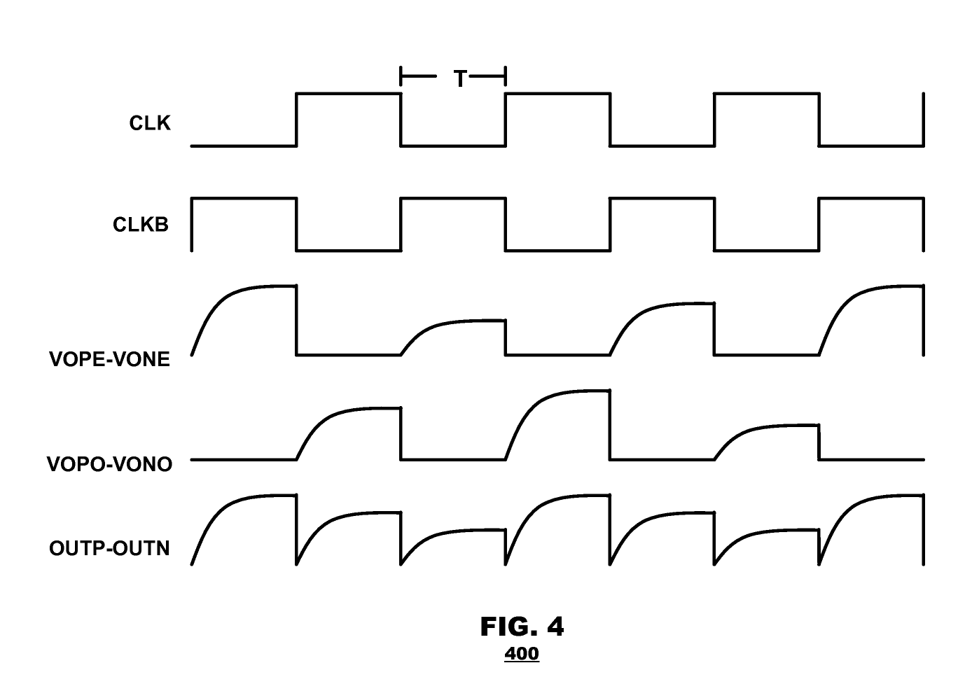

FIG. 4 is a timing diagram that illustrates the timing of the ping-pong operation according to the embodiment of the present invention described above (with reference to FIG. 3). The timing diagram will be explained with reference to the circuit 300 of FIG. 3.

Out-of-phase clocks CLK and CLKB may control the operation of switches 325, 326, SW_{SH-O}, and SW_{SH-E}. Each CH RO 321, 322 may have a half-period time of T, which is the time to output a signal from a selected pixel of a pixel array. Individual differential outputs VOPO-VONO, VOPE-VONE of respective CH ROs 321, 322 are shown in amplify and reset phases. The ping-ponging function can be realized when comparing timing diagrams for VOPE-VONE with VOPO-VONO. For example, when VOPE-VONE (which are the outputs of even CH RO 322) may be in an amplify state at a given time, VOPO-VONO (which are the outputs of odd CH RO 321) may be in a reset phase.

The combined differential output OUTP-OUTN from common output buffer 330 is also shown. As seen in the combined differential output OUTP-OUTN, an additional advantage of ping-ponging between the odd and even CH ROs 321, 322 is that no time is wasted by waiting a half-period T for an amplifier to reset. For example, while odd CH RO 321 may be in a reset phase, even CH RO 322 may be in an amplify phase (and vice versa). This effectively doubles the maximum readout rate of the system.

The techniques of the foregoing embodiments allow circuit designers to place ADCs off-chip. Consequently, the heat dissipated by the ADCs is away from the image sensor. Additionally, because the foregoing techniques reduce the number of parallel ADCs required, the number of potential sources of fixed-pattern noise is reduced.

Although the foregoing techniques have been described above with reference to specific embodiments, the invention is not limited to the above embodiments and the specific configurations shown in the drawings. For example, some components shown may be combined with each other as one embodiment, or a component may be divided into several subcomponents, or any other known or available component may be added. Further, although it has been convenient to refer to the CROs of the foregoing embodiments as being associated with “columns” of the array, such designations should not be interpreted to exclude CROs being associated with “rows” of the array. Moreover, although the preceding discussion has presented the column readout circuits as connected to “columns” of the pixel array, the discussion is not meant to impose any specific orientation with respect to the array; the principles of the present invention also extend to configurations in which the readout circuits are connected instead to respective rows of a pixel array. Those skilled in the art will appreciate that these techniques may be implemented in other ways without departing from the sprit and substantive features of the invention. The present embodiments are therefore to be considered in all respects as illustrative and not restrictive.

We claim:

1. A readout system for an image device, comprising:
a plurality of parallel first stage readout circuits, each comprising:
a pair of sampling capacitors, first terminals of which are connected to a common input by a respective input switch and to each other by a transfer switch; and
a pair of selection switches each coupling second terminals of the capacitors to respective readout lines; and
a channel readout circuit having a pair of inputs coupled to respective readout lines and comprising:
an amplifier having inputs respectively coupled to the readout lines;
a pair of feedback capacitors, each coupled to a respective input and a respective output of the amplifier, and
a pair of switches, each connecting a respective input of the amplifier to a common-mode voltage that has a same voltage as a supply voltage of the amplifier.

2. The readout system of claim 1, wherein the number of first stage readout circuits matches a number of columns of an associated pixel array.

3. The readout system of claim 1, wherein the number of first stage readout circuits is fewer than a number of columns of an associated pixel array.

4. The readout system of claim 1, wherein the first capacitor is for storage of charge representing a reset pixel value output from an associated pixel array and the second capacitor is for storage of charge representing a signal value output from the pixel array.

5. A readout system for an image device, comprising:
a plurality of parallel first stage readout circuits, each comprising:
a pair of sampling capacitors, first terminals of which are connected to a common input by a respective input switch and to each other by a transfer switch; and
a pair of selection switches each coupling second terminals of the capacitors to output terminals of the first stage readout circuits; and
a pair of channel readout circuits each having a pair of inputs coupled to output terminals of half of the first stage readout circuits, the channel readout circuits each comprising:
an amplifier having inputs coupled to the channel readout circuit's inputs;
a pair of feedback capacitors, each coupled to a respective input and a respective output of the amplifier; and
a pair of switches, each connecting a respective input of the associated amplifier to a common-mode voltage that has a same voltage as a supply voltage of the associated amplifier.

6. The readout system of claim 5, wherein the number of first stage readout circuits matches a number of columns of an associated pixel array.

7. The readout system of claim 5, wherein
a first of the channel readout circuits and the first stage readout circuits connected thereto are associated with columns of an associated pixel array in odd-numbered positions, and
a second of the channel readout circuits and the first stage readout circuits connected thereto are associated with columns of the pixel array in even-numbered positions.

8. The readout system of claim 5, wherein the first capacitor is for storage of charge representing a reset pixel value output from an associated pixel array and the second capacitor is for storage of charge representing a signal value output from the pixel array.

9. The readout system of claim 5, wherein the channel readout circuits each further comprise a pair of switches each connecting a respective amplifier input to a common-mode voltage.

10. A readout circuit for an image device, comprising:
a plurality of column readout circuits each for storing, in respective first and second capacitors, charge representing signal and reset values received from a selected pixel in a pixel array and for transferring a charge representing a difference in charge stored on the first and second capacitors;
a differential channel readout circuit for receiving the charge difference from the column readout circuit and for storing the charge difference in a pair of feedback capacitors provided about an amplifier, and
routing fabric coupling the column readout circuits to the differential channel readout circuit.

11. The readout circuit of claim 10, further comprising a pair of switches, each coupling a respective input of the amplifier to a common-mode voltage that has a same voltage as a supply voltage of the associated amplifier.

12. The readout circuit of claim 10, further comprising a pair of selection switches, each coupling one of the first and second capacitors to a respective feedback capacitor.

13. The readout circuit of claim 10, further comprising a transfer switch coupling input terminals of the first and second capacitors to each other.

14. The readout circuit of claim 10, wherein each column readout circuit performs correlated double sampling in conjunction with the differential channel readout circuit.

15. The readout circuit of claim 10, wherein the column readout circuit and the differential channel readout circuit are connected to, and disconnected from, each other using a routing fabric.

16. An image device, comprising:
a pixel array with a plurality of pixel circuits arranged into an array of columns and rows;
a plurality of column readout circuits, one provided for each column of the pixel array, each for storing, in respective first and second capacitors, charge representing reset and signal values received from a selected pixel in the pixel array and for transferring a charge signal representing a difference in stored charge; and
a differential channel readout circuit for receiving the charge difference from each column readout circuit and for storage of the corresponding charge difference in a pair of feedback capacitors provided about an amplifier, inputs of the amplifier connected by respective coupling switches to a common-mode voltage that has a same voltage as a supply voltage of the amplifier.

17. The image device of claim 16, wherein the column readout circuits each comprise a pair of sampling capacitors, first terminals of which are connected to a common input by a respective input switch and to each other by a transfer switch.

18. The readout circuit of claim 16, wherein, in each column readout circuit, the first capacitor stores a signal value from the selected pixel of the pixel array and the second capacitor stores a reset value from the selected pixel of the pixel array.

19. The readout circuit of claim 18, wherein the charge difference represents a difference in charge between the signal and reset values stored by each column readout circuit.

20. The readout circuit of claim 16, wherein each column readout circuit performs correlated double sampling in conjunction with the differential channel readout circuit.

21. The readout circuit of claim 16, wherein each column readout circuit and the differential channel readout circuit are connected to, and disconnected from, each other using a routing fabric.

22. The readout circuit of claim 16, wherein, in each column readout circuit, when each charge difference is transferred from the first and second capacitors to the third and fourth capacitors of the differential channel readout circuit, the voltage across the first and second capacitors is amplified.

23. The readout circuit of claim 16, wherein the amplified voltage is outputted from the channel readout circuit.

24. An image device, comprising:
a pixel array with a plurality of pixel circuits arranged into an array of columns and rows;
a plurality of odd column readout circuits, one provided for each odd numbered column of the pixel array, each for storing charge, received from a selected odd pixel in the pixel array, in a first and second capacitor and for transferring an odd charge difference representing a difference in charge between the first and second capacitor;
a plurality of even column readout circuits, one provided for each even numbered column of the pixel array, each for storing charge, received from a selected even pixel in the pixel array, in a third and fourth capacitor and for transferring an even charge difference representing a difference in charge between the third and fourth capacitor;
an odd differential channel readout circuit for receiving the odd charge difference from each odd column readout circuit and for storing the corresponding odd charge difference in a fifth and sixth capacitor provided in feedback arrangement about a common first amplifier, inputs of the amplifier connected by respective coupling switches to a common-mode voltage that has a same voltage as a supply voltage of the first amplifier;
an even differential channel readout circuit for receiving the even charge difference from each even column readout circuit and storing the corresponding even charge difference in a seventh and eighth capacitor provided in feedback arrangement about a common second amplifier, inputs of the amplifier connected by respective coupling switches to a common-mode voltage that has a same voltage as a supply voltage of the second amplifier;
a common output buffer that receives output signals from the odd and even differential channel readout circuits;
a controller to place the even and odd channel readout circuits in reset states and amplification states respectively, the even channel readout circuit being in reset state while the odd channel readout circuit is in amplification state, the odd channel readout circuit being in reset state while the even channel readout circuit is in amplification state.

25. The image device of claim 24, wherein each column readout circuit further comprises a pair of switches, each coupling a respective input of the amplifier to a common-mode voltage source.

26. The image device of claim 24, wherein the column readout circuits each comprise a pair of sampling capacitors, first terminals of which are connected to a common input by a respective input switch and to each other by a transfer switch.

27. The image device of claim 24, wherein, in each odd column readout circuit, the first capacitor stores a signal value from the selected odd pixel of the pixel array and the second capacitor stores a reset value from the selected odd pixel of the pixel array.

28. The image device of claim 27, wherein, in each even column readout circuit, the third capacitor stores a signal value from the selected even pixel of the pixel array and the fourth capacitor stores a reset value from the selected even pixel of the pixel array.

29. The image device of claim 24, wherein each odd and even column readout circuit performs correlated double sampling in conjunction with the differential channel readout circuit.

30. The image device of claim 24, wherein each odd and even column readout circuit is coupled to a corresponding odd and even differential channel readout circuit using a routing fabric.

31. A readout system for an image device, comprising:
a plurality of parallel first stage readout circuits, each comprising:
a pair of sampling capacitors, first terminals of which are connected to a common input by a respective input switch and to each other by a transfer switch; and
a pair of selection switches each coupling second terminals of the capacitors to respective readout lines; and
a channel readout circuit having a pair of inputs coupled to respective readout lines and comprising:
an amplifier having inputs coupled to the readout lines;
a pair of feedback capacitors, each coupled to a respective input and a respective output of the amplifier.
